(19) United States
(12) Patent Application Publication
(10) Pub. No.: US 2012/0305053 A1
(43) Pub. Date: Dec. 6, 2012

(54) SOLAR CELL AND MANUFACTURING METHOD THEREOF

(75) Inventors: Takeyuki SEKIMOTO, Anpachi-gun (JP); Shigeo YATA, Ogaki-shi (JP); Mitsuhiro MATSUMOTO, Gifu-shi (JP)

(73) Assignee: SANYO Electric Co., Ltd., Moriguchi-shi (JP)

(21) Appl. No.: 13/585,496

(22) Filed: Aug. 14, 2012

Related U.S. Application Data
(63) Continuation of application No. PCT/JP2011/051782, filed on Jan. 28, 2011.

(30) Foreign Application Priority Data
Feb. 26, 2010 (JP) 2010-041484

(51) Int. Cl. H01L 31/052; H01L 31/18

(52) U.S. Cl. 136/246; 438/72; 257/E31.127

(57) ABSTRACT

Disclosed is a solar cell which allows more photogenerated carriers to be extracted while improving power generation efficiency. The solar cell has a light-receiving surface electrode layer (2), a first photoelectric conversion unit (31) layered over the light-receiving surface electrode layer (2), a reflective layer (32) comprising SiO and layered over the first photoelectric conversion unit (31), a second photoelectric conversion unit (33) layered over the reflective layer (32), and a backside electrode layer (4) layered over the second photoelectric conversion unit (33). An oxygen concentration of the reflective layer (32) is higher on a side of the second photoelectric conversion unit (33) than on a side of the first photoelectric conversion unit (31).

### CROSS-REFERENCE TO RELATED APPLICATION

The present application is a continuation application of International Application No. PCT/JP2011/051782, filed Jan. 28, 2011, the entire contents of which are incorporated herein by reference and priority to which is hereby claimed. The PCT/JP2011/051782 application claimed the benefit of the date of the earlier filed Japanese Patent Application No. 2010-041484 filed Feb. 26, 2010, the entire contents of which are incorporated herein by reference, and priority to which is hereby claimed.

### TECHNICAL FIELD

The present invention relates to a solar cell having a reflective layer which reflects a part of incident light.

### BACKGROUND ART

Solar cells are much lauded as a new source of energy because the solar cells can directly convert light from the sun, which is a source of clean and infinite energy, into electricity.

In general, a solar cell comprises a photoelectric conversion unit which absorbs light incident on the solar cell and generates photogenerated carriers between a transparent electrode layer provided on the side of incidence of light and a backside electrode layer provided on a side opposite to the side of incidence of light.

In the related art, it is known to provide a plurality of photoelectric conversion units as a layered structure contributing to the photoelectric conversion, so that a majority of the incident light contributes to the photoelectric conversion. Because such a structure with the plurality of photoelectric conversion units can cause a portion of light which has passed through the photoelectric conversion unit provided on the side of incidence of light without contributing to the photoelectric conversion to contribute to photoelectric conversion by another photoelectric conversion unit, an amount of light absorbed in the photoelectric conversion units is increased. As a result, the amount of photogenerated carriers generated in the photoelectric conversion units is increased, and the power generation efficiency of the solar cell is improved.

### RELATED ART REFERENCES

### Patent Literature

[Patent Literature 1] JP 4-167474 A

### DISCLOSURE OF INVENTION

### Technical Problem

However, in recent years, a further improvement of the power generation efficiency of the solar cell is desired.

In order to further improve the power generation efficiency, it is effective to increase the amount of photogenerated carriers generated in the photoelectric conversion unit. Thus, provision of a reflective layer between the plurality of photoelectric conversion units is being considered. With such a configuration, a portion of incident light can be reflected and can enter the photoelectric conversion unit on the side of the incidence of light, and, in the other photoelectric conversion units on the side of the backside electrode layer, the light, among the incident light, reflected by the backside electrode layer or the like may be again reflected and confined. As a light-transmissive conductive material which forms a main part of the reflective material as described above, silicon oxide (SiO) has been researched and developed.

However, when a reflective layer having a low refraction is used in order to reflect more light and cause the reflected light to enter the photoelectric conversion unit on the side of the incidence of light and to confine more light in the other photoelectric conversion units on the side of the backside electrode layer, there has been a problem in that a contact resistance between the reflective layer and an adjacent photoelectric conversion unit becomes large, resulting in a loss of photogenerated carriers which are generated.

The present invention has been made in view of the above-described problem, and an advantage of the present invention is provision of a solar cell having an improved power generation efficiency.

### Solution to Problem

According to one aspect of the present invention, there is provided a solar cell comprising a light-receiving surface electrode layer, a first photoelectric conversion unit layered over the light-receiving surface electrode layer, a reflective layer comprising SiO and layered over the first photoelectric conversion unit, a second photoelectric conversion unit layered over the reflective layer, and a backside electrode layer layered over the second photoelectric conversion unit, wherein an oxygen concentration of the reflective layer becomes higher from a side of the first photoelectric conversion unit toward a side of the second photoelectric conversion unit.

According to another aspect of the present invention, there is provided a method of manufacturing a solar cell comprising a step A in which a light-receiving surface electrode layer is formed, a step B in which a first photoelectric conversion unit is formed over the light-receiving surface electrode layer, a step C in which a reflective layer comprising SiO is formed over the first photoelectric conversion unit, a step D in which a second photoelectric conversion unit is formed over the reflective layer, and a step E in which a backside electrode layer is formed over the second photoelectric conversion unit, wherein, in step C, the reflective layer is formed such that an oxygen concentration of the reflective layer becomes higher from a side of the first photoelectric conversion unit toward a side of the second photoelectric conversion unit.

### Advantageous Effect of Invention

According to various aspects of the present invention, a solar cell can be provided in which loss of the photogenerated carriers which are generated can be inhibited and power generation efficiency is improved.

### BEST MODE FOR CARRYING OUT THE INVENTION

Preferred embodiments of the present invention will now be described with reference to the drawings. In the following description of the drawings, a same or similar element is assigned the same or similar reference numeral. However, it should be noted that the drawings are schematic, and ratios or the like of the sizes differ from the actual values. Therefore, the specific size or the like should be judged in consideration of the following description. In addition, different relationships or ratios between sizes may be included among the drawings.

### First Preferred Embodiment

### <Structure of Solar Cell>

A structure of a solar cell according to a first preferred embodiment of the present invention will now be described with reference to FIG. 1.

FIG. 1 is a cross sectional diagram of a solar cell 10 according to a first preferred embodiment of the present invention.

The solar cell 10 comprises a substrate 1, a light-receiving surface electrode layer 2, a layered structure 3, and a backside electrode layer 4.

The substrate 1 is transmissive to light, and is made of a light-transmissive material such as glass and plastic.

The light-receiving surface electrode layer 2 is layered over the substrate 1, and is electrically conductive and transmissive to light. For the light-receiving surface electrode layer 2, a metal oxide such as tin oxide (SnO₂), zinc oxide (ZnO), indium oxide (In₂O₂), titanium oxide (TiO₂), or the like may be used. Alternatively, these metal oxides may be doped with fluorine (F), tin (Sn), aluminum (Al), iron (Fe), gallium (Ga), niobium (nb), or the like.

The layered structure 3 is providedbetween the light-receiving surface electrode layer 2 and the backside electrode layer 4. The layered structure 3 comprises a first photoelectric conversion unit 31, a reflective layer 32, and a second photoelectric conversion unit 33.

The first photoelectric conversion unit 31, the reflective layer 32, and the second photoelectric conversion unit 33 are layered in order from the side of the light-receiving surface electrode layer 2.

The first photoelectric conversion unit 31 generates photogenerated carriers by light incident from the side of the light-receiving surface electrode layer 2 or by light reflected by the reflective layer 32. The first photoelectric conversion unit 31 comprises a pin junction in which a p-type amorphous silicon semiconductor, an i-type amorphous silicon semiconductor, and an n-type amorphous silicon semiconductor are layered from the side of the substrate 1 (not shown in the drawings).

The reflective layer 32 reflects a part of light transmitted through the first photoelectric conversion unit 31 to the side of the first photoelectric conversion unit 31. The reflective layer 32 is sequentially layered from the side of the first photoelectric conversion unit 31 in a contacted manner.

For the reflective layer 32, silicon oxide (SiO) is used as the primary light-transmissive conductive material. For SiO which is used here, a structure is employed in which an oxygen concentration within the layer becomes higher from the side of the first photoelectric conversion unit 31 toward the side of the second photoelectric conversion unit 33 which will be described later. In the present embodiment, the change of the oxygen concentration in the SiO layer is such that the oxygen concentration becomes higher from the side of the first photoelectric conversion unit 31 toward the side of the second photoelectric conversion unit 33 at a constant rate, but the present invention is not limited to such a configuration, and alternatively, the oxygen concentration may be stepwise increased. In other words, it is sufficient that the oxygen concentration of the SiO layer is such that the oxygen concentration is higher on the side of the second photoelectric conversion unit 33 than the side of the first photoelectric conversion unit 31. In addition, in the present embodiment, a reflective layer 32 is formed to a thickness of 50 nm, but the present invention is not limited to such a configuration, and the thickness is preferably set in a range of 30 nm-150 nm.

The second photoelectric conversion unit 33 generates photogenerated carriers by light incident from the side of the light-receiving surface electrode layer 2 and transmitted through the first photoelectric conversion unit 31, or light reflected by the backside electrode layer 4. The second photoelectric conversion unit 33 has a pin junction in which a p-type microcrystalline silicon semiconductor, an i-type microcrystalline silicon semiconductor, and an n-type microcrystalline silicon semiconductor are layered from the side of the substrate 1 (not shown in the drawings).

The backside electrode layer 4 comprises one or a plurality of layers having electrical conductivity. For the backside electrode layer 4, ZnO, silver (Ag), or the like may be used, and in the present embodiment, the backside electrode layer has a structure in which a layer including ZnO and a layer including Ag are layered from the side of the layered structure 3. However, the present invention is not limited to such a configuration, and alternatively, the backside electrode layer 4 may have only the layer including Ag.

### <Operation and Advantages>

Advantages of the solar cell 10 according to the first preferred embodiment of the present invention will now be described in detail.

(1) In the solar cell 10, the oxygen concentration of the reflective layer 32 is set such that the oxygen concentration becomes higher from the side of the first photoelectric conversion unit 31 toward the side of the second photoelectric conversion unit 33. With such a configuration, the following advantages can be obtained.

(a) Because the reflective layer 32 is formed such that the oxygen concentration becomes higher from the side of the first photoelectric conversion unit 31 toward the side of the second photoelectric conversion unit 33, the oxygen concentration at the side of the reflective layer 32, near the first photoelectric conversion unit 31, is lower than an average oxygen concentration of the reflective layer 32, and a film having a high index of refraction is formed. On the other hand, at the side, of the reflective layer 32, near the second photoelectric conversion unit 33, the oxygen concentration is higher compared to the average oxygen concentration of the reflective layer 32, and a film with a low index of refraction is formed. As a result, the index of refraction is balanced for the overall reflective layer 32, and the optical characteristic of the overall reflective layer 32 is similar to that of a film of the reflective layer 32 having the average oxygen concentration uniform throughout the reflective layer 32. That is, with the lower oxygen concentration of the reflective layer 32 on the side of the first photoelectric conversion unit 31, the contact resistance caused at a contact interface between the reflective layer 32 having a high oxygen concentration and the first photoelectric conversion unit 31 can be inhibited, and with the high oxygen concentration in the reflective layer 32 on the side of the second photoelectric conversion unit 33, the index of refraction of the overall reflective layer 32 can be increased, and as a result, the reflectivity at the interface between the reflective layer 32 and the first photoelectric conversion unit 31, or at the interface between the reflective layer 32 and the second photoelectric conversion unit 33, can be increased. As a result, it is possible to inhibit an increase in a series resistance value of the solar cell 10 caused by the high contact resistance between the reflective layer 32 having a high oxygen concentration and the first photoelectric conversion unit 31 comprising silicon, while improving the reflection effect at the interface between the reflective layer 32 and the first photoelectric conversion unit 31 or at the interface between the reflective layer 32 and the second photoelectric conversion unit 33.

Therefore, in the solar cell 10, it is possible to inhibit reduction in a fill factor (F.F.) of the solar cell 10 due to an increase in the series resistance value and to improve the reflectivity at the interface between the reflective layer 32 and the first photoelectric conversion unit 31 or between the reflective layer 32 and the second photoelectric conversion unit 33, to increase the short-circuit current and improve the power generation efficiency of the solar cell 10.

(b) In the present embodiment, the reflective layer 32 is formed such that the CO₂ flow rate is higher at the time of completion of the film formation than at the time of start of the film formation. As a result, crystallization tends to occur less frequently at the time of completion of the film formation than at the time of start of the film formation, and the increase in crystallization percentage of the reflective layer 32 can be inhibited. Because of this, the amount of amorphous composition which can more easily capture more oxygen compared to the crystalline composition may be increased, and the oxygen concentration can be further increased, and as a consequence, the light absorption loss at the reflective layer 32 can be reduced.

By setting the index of refraction of the overall reflective layer 32 with respect to the light of a wavelength of 550 nm to less than 2.4, it is possible to set the reflectivity at the interface with the silicon having an index of refraction of about 4.3 to greater than or equal to 8%. With such a configuration, the amount of light entering the first photoelectric conversion unit 31 comprising amorphous silicon can be increased, and an advantage similar to a case where the thickness of the first photoelectric conversion unit 31 is increased can be substantially obtained. As a result, the light degradation of the first photoelectric conversion unit 31 which becomes a problem as the thickness is increased can be inhibited, and the reduction of the amount of photogenerated carriers generated in the first photoelectric conversion unit 31 can be inhibited.

(2) In the solar cell 10 according to the first preferred embodiment of the present invention, SiO used for the reflective layer 32 is microcrystalline. Because of this, the following advantages can be obtained.

(a) By setting the reflective layer 32 to be microcrystalline and to include crystalline composition in the amorphous SiO, it is possible to improve the electrical conductivity compared to a structure formed only with the amorphous SiO.

(b) When the microcrystalline silicon is employed for the second photoelectric conversion unit 33, with the use of the microcrystalline silicon for the reflective layer 32, it is possible to grow crystals for the second photoelectric conversion unit 33 using the reflective layer 32 as an underlying layer, and as a result, superior crystallization can be achieved. Consequently, the film characteristic of the second photoelectric conversion unit 33 can be improved and the power generation efficiency of the solar cell 10 can be improved.

### Other Preferred Embodiments

The present invention is described above with reference to the preferred embodiment, but the above description and drawings which are a part of this disclosure should not be understood to limit the present invention. Various alternative embodiments, examples, and operational techniques may become apparent to a person with ordinary skill in the art based on this disclosure.

For example, in the first preferred embodiment described above, 2 photoelectric conversion units (the first photoelectric conversion unit 31 and the second photoelectric conversion unit 33) are included in the layered structure 3, but the present invention is not limited to such a configuration. More specifically, the layered structure 3 may comprise 3 or more photoelectric conversion units. In such a case, the reflective layer 32 may be provided between 2 arbitrary adjacent photoelectric conversion units.

In addition, in the first preferred embodiment described above, the first photoelectric conversion unit 31 has the pin junction in which the p-type amorphous silicon semiconductor, the i-type amorphous silicon semiconductor, and the n-type amorphous silicon semiconductor are layered from the side of the substrate 1, but the present invention is not limited to such a configuration. More specifically, the first photoelectric conversion unit 31 may have a pin junction in which a p-type crystalline silicon semiconductor, an i-type crystalline silicon semiconductor, and an n-type crystalline silicon semiconductor are layered from the side of the substrate 1. The “crystalline silicon” includes microcrystalline silicon and polycrystalline silicon.

Moreover, in the first preferred embodiment described above, the second photoelectric conversion unit 33 has the pin junction in which the p-type microcrystalline silicon semiconductor, the i-type microcrystalline silicon semiconductor, and the n-type microcrystalline silicon semiconductor are layered from the side of the substrate 1, but the present invention is not limited to such a configuration. More specifically, the second photoelectric conversion unit 33 may have a pin junction in which a p-type amorphous silicon semiconductor, an i-type amorphous silicon semiconductor, and an n-type amorphous silicon semiconductor are layered from the side of the substrate 1.

Furthermore, in the first preferred embodiment described above, the first photoelectric conversion unit 31 and the second photoelectric conversion unit 33 have the pin junction, but the present invention is not limited to such a configuration. More specifically, at least one of the first photoelectric conversion unit 31 and the second photoelectric conversion unit 33 may have a pn junction in which a p-type silicon semiconductor and an n-type silicon semiconductor are layered from the side of the substrate 1.

In addition, in the first preferred embodiment described above, the solar cell 10 has a structure in which the light-receiving surface electrode layer 2, the layered structure 3, and the backside electrode layer 4 are layered in order over the substrate 1, but the present invention is not limited to such a configuration. More specifically, the solar cell 10 may have a structure in which the backside electrode layer 4, the layered structure 3, and the light-receiving surface electrode layer 2 are layered in order over the substrate 1.

As described, the present invention clearly includes various embodiments or the like which are not explicitly described herein. Therefore, the technical scope of the present invention is determined from the invention specifying items related to the claims reasonable from the above description.

### EXAMPLES

The solar cell according to the present invention will now be specifically described with reference to Examples. However, the present invention is not limited to the structures described below in the Examples, and the structure may be suitably modified within a range that does not change the idea of the invention.

### Example

A solar cell 10 according to a first Example was manufactured in the following manner.

First, over a glass substrate (substrate 1) having a thickness of 4 mm, a SnO₂ layer (light-receiving electrode layer 2) having a recess-and-projection shape over the surface and a thickness of 600 nm was formed through thermal CVD.

Next, over the SnO₂ layer (light-receiving surface electrode layer 2), a p-type amorphous silicon semiconductor, an i-type amorphous silicon semiconductor, and an n-type amorphous silicon semiconductor were sequentially layered through plasma CVD, to form a first cell (first photoelectric conversion unit 31).

For the plasma CVD, for example, RF plasma CVD of 13.56 MHz is preferably applied. The input power density of the plasma is preferably greater than or equal to 5 mW/cm² and less than or equal to 100 mW/cm².

Next, over the first photoelectric conversion unit 31, a reflective layer 32 comprising SiO was formed through plasma CVD. When the reflective layer 32 was formed, a flow rate of CO₂ was incremented at a constant percentage from 120 sccm to 180 sccm from the start of the film formation to completion of the film formation. That is, if the flow rate ratio of the flow rate of CO₂ with respect to a flow rate of SiH₄ at the start of the film formation was standardized as 1.0 (hereinafter, values standardized with the flow rate ratio of the flow rate of CO₂ with respect to the flow rate of SiH₄ at the start of the film formation as 1.0 will be described), the flow rate of SiH₄ was not changed during the film formation, and the flow rate of CO₂ was changed at a constant percentage, so that the flow rate ratio of CO₂/SiH₄ was 1.0 to 1.5 and an average of the flow rate ratio of CO₂/SiH₄ was 1.25 over the entire reflective layer 32.

The reflectivity can be increased as the difference in the indices of refraction of contacting surfaces is increased. Because the index of refraction of a material mainly comprised of silicon with respect to the light of a wavelength of 550 nm is about 4.3, the average flow rate ratio of CO₂/SiH₄ during film formation of the reflective layer 32 is preferably adjusted such that the index of refraction of the overall reflective layer 32 comprising SiO is less than 2.4.

Alternatively, in place of CO₂, for example, CO or O₂ may be used, and in place of SiH₄, for example, Si₂H₆ may be used.

Next, over the reflective layer 32, a p-type microcrystalline silicon semiconductor, an i-type microcrystalline silicon semiconductor, and an n-type microcrystalline silicon semiconductor were layered through plasma CVD, to form the second photoelectric conversion unit 33.

For the plasma CVD, similar to the first photoelectric conversion unit 31, the RF plasma CVD of 13.56 MHz is preferably applied. The input power density of plasma is preferably greater than or equal to 5 mW/cm² and less than or equal to 100 mW/cm².

Then, over the second photoelectric conversion unit 33, a ZnO layer and a Ag layer (backside electrode layer 4) were formed through sputtering.

TABLE 1 shows film formation conditions of the first photoelectric conversion unit 31, the reflective layer 32, and the second photoelectric conversion unit 33 described above. Thicknesses of the ZnO layer and the Ag layer (backside electrode layer 4) were set to 90 nm and 200 nm, respectively.

TABLE 1

| | | SUBSTRATE | GAS FLOW | REACTION | RF | |
|---|---|---|---|---|---|---|
| | | TEMPERATURE | RATE | PRESSURE | POWER | THICKNESS |
| | | (° C.) | (sccm) | (Pa) | (W) | (nm) |
| FIRST | p-TYPE | 180 | SiH₄: 300 | 106 | 10 | 15 |
| PHOTOELECTRIC | | | CH₄: 300 | | | |
| CONVERSION | | | H₂: 2000 | | | |
| UNIT 31 | | | B₂H₆: 3 | | | |
| | i-TYPE | 200 | SiH₄: 300 | 106 | 20 | 200 |
| | | | H₂: 2000 | | | |
| | n-TYPE | 180 | SiH₄: 300 | 133 | 20 | 30 |
| | | | H₂: 2000 | | | |
| | | | PH₃: 5 | | | |
| REFLECTIVE | SiO | 180 | SiH₄: 80 | 250 | 2300 | 50 |
| LAYER 32 | | | H₂: 24000 | | | |
| | | | PH₃: 2 | | | |
| | | | CO₂: 120→180 | | | |
| SECOND | p-TYPE | 180 | SiH₄: 10 | 106 | 10 | 30 |
| PHOTOELECTRIC | | | H₂: 2000 | | | |
| CONVERSION | | | B₂H₆: 3 | | | |
| UNIT 33 | i-TYPE | 200 | SiH₄: 100 | 133 | 20 | 2000 |
| | | | H₂: 2000 | | | |
| | n-TYPE | 200 | SiH₄: 10 | 133 | 20 | 20 |
| | | | H₂: 2000 | | | |
| | | | PH₃: 5 | | | |

With the process described above, in the first Example, a solar cell 10 was formed in which, as shown in TABLE 1, the reflective layer 32 comprising microcrystalline SiO and having an oxygen concentration increased from the side of the first photoelectric conversion unit 31 toward the side of the second photoelectric conversion unit 33 was provided between the first photoelectric conversion unit 31 and the second photoelectric conversion unit 33.

### First Comparative Example

A solar cell 20 of a first Comparative Example was manufactured in the following manner.

First, similar to the above-described first Example, over a glass substrate (substrate 21) having a thickness of 4 mm, a SnO₂ layer (light-receiving surface electrode layer 122) having a recess-and-projection shape on the surface and a thickness of 600 nm, and a first photoelectric conversion unit 131 were sequentially formed through thermal CVD.

Next, over the first photoelectric conversion unit 131, a reflective layer 132 comprising SiO was formed through plasma CVD. In the first Comparative Example, the reflective layer 132 was formed with CO₂/SiH₄ at constant flow rate ratio of 1.0. In other words, the reflective layer 132 was formed while the flow rate ratio was unchanged and set to the flow rate ratio of the flow rate of CO₂ with respect to the flow rate of SiH₄ at the start of the film formation.

Then, in a similar manner to the above-described Example, over the reflective layer 132, a second photoelectric conversion unit 133, and a ZnO layer and a Ag layer (backside electrode layer 14) were sequentially formed.

TABLE 2 shows film formation conditions of the reflective layer 132 described above. The film formation conditions of the first photoelectric conversion unit 131 and the second photoelectric conversion unit 133 were similar to the film formation conditions in the above-described Example. The thicknesses of the ZnO layer and the Ag layer (backside electrode layer 14) were set to 90 nm and 200 nm, respectively, similar to the above-described Example.

TABLE 2

| | | SUBSTRATE | GAS FLOW | REACTION | RF | |
|---|---|---|---|---|---|---|
| | | TEMPERATURE | RATE | PRESSURE | POWER | THICKNESS |
| | | (° C.) | (sccm) | (Pa) | (W) | (nm) |
| FIRST | p-TYPE | 180 | SiH₄: 300 | 106 | 10 | 15 |
| PHOTOELECTRIC | | | CH₄: 300 | | | |
| CONVERSION | | | H₂: 2000 | | | |
| UNIT 131 | | | B₂H₆: 3 | | | |
| | i-TYPE | 200 | SiH₄: 300 | 106 | 20 | 200 |
| | | | H₂: 2000 | | | |
| | n-TYPE | 180 | SiH₄: 300 | 133 | 20 | 30 |
| | | | H₂: 2000 | | | |
| | | | PH₃: 5 | | | |
| REFLECTIVE | SiO | 180 | SiH₄: 80 | 250 | 2300 | 50 |
| LAYER 132 | | | H₂: 24000 | | | |
| | | | PH₃: 2 | | | |
| | | | CO₂: 120 | | | |
| SECOND | p-TYPE | 180 | SiH₄: 10 | 106 | 10 | 30 |
| PHOTOELECTRIC | | | H₂: 2000 | | | |
| CONVERSION | | | B₂H₆: 3 | | | |
| UNIT 133 | i-TYPE | 200 | SiH₄: 100 | 133 | 20 | 2000 |
| | | | H₂: 2000 | | | |
| | n-TYPE | 200 | SiH₄: 10 | 133 | 20 | 20 |
| | | | H₂: 2000 | | | |
| | | | PH₃: 5 | | | |

With the above-described process, in the present Comparative Example, the solar cell 20 was formed having the reflective layer 132 between the first photoelectric conversion unit 131 and the second photoelectric conversion unit 133 as shown in FIG. 2, the reflective layer being formed by supplying CO₂/SiH₄ at a constant flow rate ratio of 1.0, having a constant oxygen concentration, and comprising microcrystalline SiO.

### Second Comparative Example

A solar cell 30 of a second Comparative Example was manufactured in the following manner.

First, similar to the above-described first Example, over a glass substrate (substrate 21) having a thickness of 4 mm, a SnO₂ layer (light-receiving surface electrode layer 222) having a recess-and-projection shape over the surface and a thickness of 600 nm, and a first photoelectric conversion unit 131 were sequentially formed through thermal CVD.

Next, over the first photoelectric conversion unit 131, a reflective layer 232 comprising SiO was formed through plasma CVD. In the second Comparative Example, the reflective layer 232 was formed while supplying CO₂/SiH₄ at a constant flow rate ratio of 1.25.

Then, similar to the above-described Example, over the reflective layer 232, a second photoelectric conversion unit 133, and a ZnO layer and a Ag layer (backside electrode layer 14) were sequentially formed.

TABLE 3 shows film formation conditions of the above-described reflective layer 232. The film formation conditions of the first photoelectric conversion unit 131 and the second photoelectric conversion unit 133 were similar to the film formation conditions in the above-described Example. In addition, thicknesses of the ZnO layer and the Ag layer (backside electrode layer 14) were set to 90 nm and 200 nm, respectively, similar to the above-described Example.

TABLE 3

| | | SUBSTRATE | GAS FLOW | REACTION | RF | |
|---|---|---|---|---|---|---|
| | | TEMPERATURE | RATE | PRESSURE | POWER | THICKNESS |
| | | (° C.) | (sccm) | (Pa) | (W) | (nm) |
| FIRST | p-TYPE | 180 | SiH₄: 300 | 106 | 10 | 15 |
| PHOTOELECTRIC | | | CH₄: 300 | | | |
| CONVERSION | | | H₂: 2000 | | | |
| UNIT 131 | | | B₂H₆: 3 | | | |
| | i-TYPE | 200 | SiH₄: 300 | 106 | 20 | 200 |
| | | | H₂: 2000 | | | |
| | n-TYPE | 180 | SiH₄: 300 | 133 | 20 | 30 |
| | | | H₂: 2000 | | | |
| | | | PH₃: 5 | | | |
| REFLECTIVE | SiO | 180 | SiH₄: 80 | 250 | 2300 | 50 |
| LAYER 232 | | | H₂: 24000 | | | |
| | | | PH₃: 2 | | | |
| | | | CO₂: 150 | | | |
| SECOND | p-TYPE | 180 | SiH₄: 10 | 106 | 10 | 30 |
| PHOTOELECTRIC | | | H₂: 2000 | | | |
| CONVERSION | | | B₂H₆: 3 | | | |
| UNIT 133 | i-TYPE | 200 | SiH₄: 100 | 133 | 20 | 2000 |
| | | | H₂: 2000 | | | |
| | n-TYPE | 200 | SiH₄: 10 | 133 | 20 | 20 |
| | | | H₂: 2000 | | | |
| | | | PH₃: 5 | | | |

With the above-described process, in the present Comparative Example, a solar cell 30 was formed having a reflective layer 232 between the first photoelectric conversion unit 131 and the second photoelectric conversion unit 133 as shown in FIG. 3, the reflective layer 232 being formed by supplying CO₂/SiH₄ at a constant flow rate ratio of 1.25, having a constant oxygen concentration, and comprising microcrystalline SiO.

### Third Comparative Example

A solar cell 40 of a third Comparative Example was manufactured in the following manner.

First, similar to the above-described first Example, over a glass substrate (substrate 21) having a thickness of 4 mm, a SnO₂ layer (light-receiving surface electrode layer 322) having a recess-and-projection shape over the surface and a thickness of 600 nm, and a first photoelectric conversion unit 131 were sequentially formed through thermal CVD.

Next, over the first photoelectric conversion unit 131, a reflective layer 332 comprising SiO was formed through plasma CVD. In the third Comparative Example, the reflective layer 332 was formed while supplying CO₂/SiH₄ at a constant flow rate ratio of 1.5.

Then, similar to the above-described Example, over the reflective layer 332, a second photoelectric conversion unit 133, and a ZnO layer and a Ag layer (backside electrode layer 14) were sequentially formed.

TABLE 4 shows film formation conditions of the reflective layer 332 described above. Film formation conditions of the first photoelectric conversion unit 131 and the second photoelectric conversion unit 133 were similar to the film formation conditions in the above-described Example. Thicknesses of the ZnO layer and the Ag layer (backside electrode layer 14) were set to 90 nm and 200 nm, respectively, similar to the above-described Example.

TABLE 4

| | | SUBSTRATE | GAS FLOW | REACTION | RF | |
|---|---|---|---|---|---|---|
| | | TEMPERATURE | RATE | PRESSURE | POWER | THICKNESS |
| | | (° C.) | (sccm) | (Pa) | (W) | (nm) |
| FIRST | p-TYPE | 180 | SiH₄: 300 | 106 | 10 | 15 |
| PHOTOELECTRIC | | | CH₄: 300 | | | |
| CONVERSION | | | H₂: 2000 | | | |
| UNIT 131 | | | B₂H₆: 3 | | | |
| | i-TYPE | 200 | SiH₄: 300 | 106 | 20 | 200 |
| | | | H₂: 2000 | | | |
| | n-TYPE | 180 | SiH₄: 300 | 133 | 20 | 30 |
| | | | H₂: 2000 | | | |
| | | | PH₃: 5 | | | |
| REFLECTIVE | SiO | 180 | SiH₄: 80 | 250 | 2300 | 50 |
| LAYER 332 | | | H₂: 24000 | | | |
| | | | PH₃: 2 | | | |
| | | | CO₂: 180 | | | |
| SECOND | p-TYPE | 180 | SiH₄: 10 | 106 | 10 | 30 |
| PHOTOELECTRIC | | | H₂: 2000 | | | |
| CONVERSION | | | B₂H₆: 3 | | | |
| UNIT 133 | i-TYPE | 200 | SiH₄: 100 | 133 | 20 | 2000 |
| | | | H₂: 2000 | | | |
| | n-TYPE | 200 | SiH₄: 10 | 133 | 20 | 20 |
| | | | H₂: 2000 | | | |
| | | | PH₃: 5 | | | |

With the process described above, in the present Comparative Example, a solar cell 40 was formed having a reflective layer 332 between the first photoelectric conversion unit 131 and the second photoelectric conversion unit 133 as shown in FIG. 4, the reflective layer 332 being formed by supplying CO₂/SiH₄ at a constant flow rate ratio of 1.5, having a constant oxygen concentration, and comprising SiO.

### <Characteristic Evaluation>

For the solar cells of the Example and the first-third Comparative Examples, characteristics including an open voltage, a short-circuit current, a fill factor, and a power generation efficiency were compared. TABLE 5 shows a result of the comparison. In TABLE 5, characteristic values are standardized with the value for the first Comparative Example as 1.00.

TABLE 5

| | Voc | Isc | | Eff |
|---|---|---|---|---|
| | (OPEN | (SHORT- | F.F. | (POWER |
| | VOLT- | CIRCUIT | (FILL | (GENERATION |
| | AGE) | CURRENT) | FACTOR) | EFFICIENCY) |
| EXAMPLE | 1.02 | 1.05 | 0.97 | 1.04 |
| FIRST | 1 | 1 | 1 | 1 |
| COMPARATIVE | | | | |
| EXAMPLE | | | | |
| SECOND | 1.02 | 1.05 | 0.96 | 1.03 |
| COMPARATIVE | | | | |
| EXAMPLE | | | | |
| THIRD | 1.01 | 1.04 | 0.93 | 0.97 |
| COMPARATIVE | | | | |
| EXAMPLE | | | | |

As shown in TABLE 5, in the Example, the short-circuit current is higher compared to the first Comparative Example, the fill factor is higher compared to the second and third Comparative Example, and the power generation efficiency is higher than all of the Comparative Examples.

With regard to the short-circuit current, in the solar cell 20 of the Example, compared to the first Comparative Example, the amount of oxygen within the layer was increased and the index of refraction of the overall reflective layer 32 was reduced, which resulted in an increase in the difference in the index of refraction with the first photoelectric conversion unit 31, more light reflected by the reflective layer 32, and consequently, a higher short-circuit current. Based on the short-circuit current, the film formed while the flow rate ratio of CO₂/SiH₄ was changed from 1.0-1.5 had a similar reflective effect as the film formed while the flow rate ratio of CO₂/SiH₄ was maintained constant at 1.25.

With regard to the fill factor, in the solar cell 10 of the Example, the oxygen concentration of the reflective layer 32 on the side contacting the first photoelectric conversion unit 31 was reduced compared to the second and third Comparative Examples, and, as a result, the series resistance in the solar cell 10 was reduced, and the fill factor was higher.

Therefore, with the improvement of the short-circuit current and the fill factor, more light can be incident to the first photoelectric conversion unit 31 to generate more optical carriers, the loss at the interface between the first photoelectric conversion unit 31 and the reflective layer 32 can be reduced, and more current can be extracted. It has been confirmed that the power generation efficiency can be improved in the Example compared to all of the Comparative Examples.

### BRIEF DESCRIPTION OF DRAWINGS

FIG. 1 is a cross sectional diagram of a solar cell 10 according to a first preferred embodiment (Example) of the present invention.

FIG. 2 is a cross sectional diagram of a solar cell 20 according to a first Comparative Example of the present invention.

FIG. 3 is a cross sectional diagram of a solar cell 30 according to a second Comparative Example of the present invention.

FIG. 4 is a cross sectional diagram of a solar cell 40 according to a third Comparative Example of the present invention.

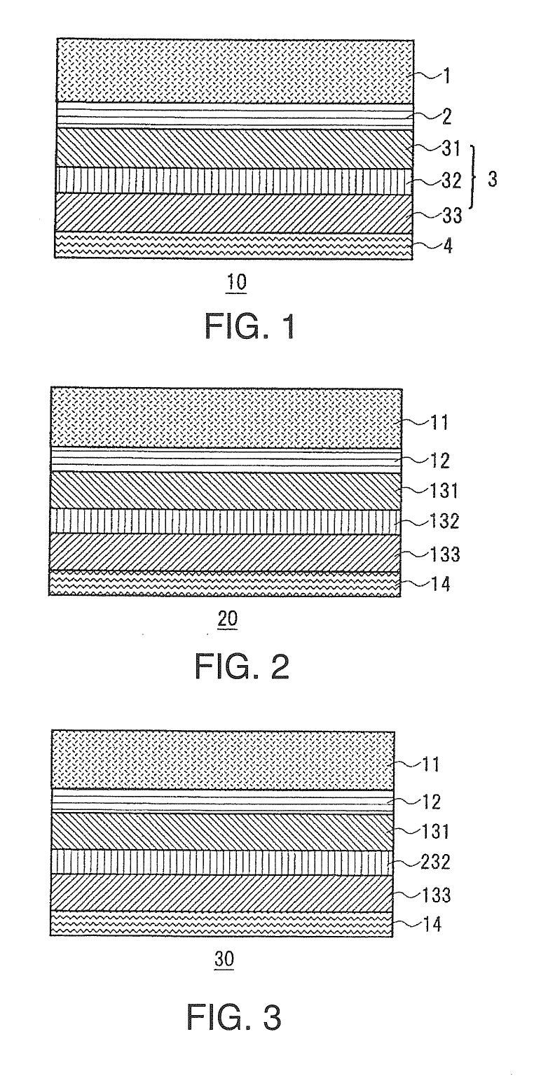

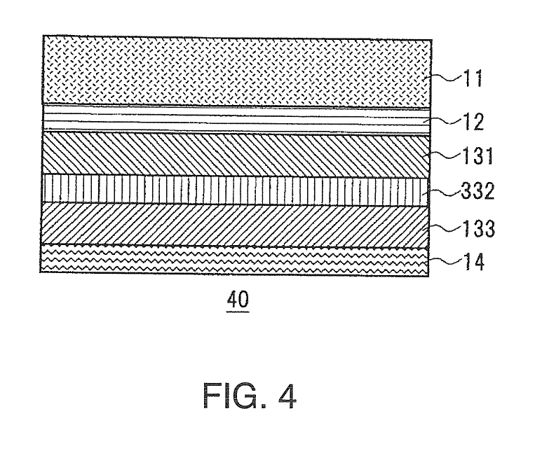

### EXPLANATION OF REFERENCE NUMERALS

1, 11 SUBSTRATE
2, 12 LIGHT-RECEIVING SURFACE ELECTRODE LAYER
3 LAYERED STRUCTURE
31, 131, 231, 331 FIRST PHOTOELECTRIC CONVERSION UNIT
32, 132, 232, 332 REFLECTIVE LAYER
33, 133, 233, 333 SECOND PHOTOELECTRIC CONVERSION UNIT
4, 14 BACKSIDE ELECTRODE LAYER
10, 20, 30, 40 SOLAR CELL

### INDUSTRIAL APPLICABILITY

The present invention is applicable to a solar cell.

1. A solar cell comprising:
a light-receiving surface electrode layer;
a first photoelectric conversion unit layered over the light-receiving surface electrode layer;
a reflective layer comprising a SiO layer and layered over the first photoelectric conversion unit;
a second photoelectric conversion unit layered over the reflective layer; and
a backside electrode layer layered over the second photoelectric conversion unit, wherein
an oxygen concentration of the reflective layer becomes higher gradually or stepwise from a side of the first photoelectric conversion unit toward a side of the second photoelectric conversion unit in an entirety in a thickness direction of the reflective layer.

2. (canceled)

3. The solar cell according to claim 1, wherein
the reflective layer comprises microcrystal.

4. A method of manufacturing a solar cell, comprising:
a step A in which a light-receiving surface electrode layer is formed;
a step B in which a first photoelectric conversion unit is formed over the light-receiving surface electrode layer;
a step C in which a reflective layer comprising SiO is formed over the first photoelectric conversion unit;
a step D in which a second photoelectric conversion unit is formed over the reflective layer; and
a step E in which a backside electrode layer is formed over the second photoelectric conversion unit, wherein
in the step C, the reflective layer is formed such that an oxygen concentration of the reflective layer becomes higher gradually or stepwise from a side of the first photoelectric conversion unit toward a side of the second photoelectric conversion unit in an entirety in a thickness direction of the reflective layer.

5. The manufacturing method of the solar cell according to claim 4, wherein
the step C is a step in which the reflective layer is formed through plasma CVD using gas including silicon and gas including oxygen, and with a flow rate of the gas including oxygen being higher at a time of completion of film formation compared to a time of start of the film formation.
